(19) United States
(12) Patent Application Publication
(10) Pub. No.: US 2023/0321790 A1
(43) Pub. Date: Oct. 12, 2023

(54) ORIGIN DETERMINATION METHOD AND GRINDING MACHINE

(71) Applicant: DISCO CORPORATION, Tokyo (JP)

(72) Inventors: Yasuyuki TAKEISHI, Tokyo (JP); Hideki MATSUI, Tokyo (JP)

(21) Appl. No.: 18/192,080

(22) Filed: Mar. 29, 2023

(30) Foreign Application Priority Data
Apr. 6, 2022 (JP) 2022-063226

(51) Int. Cl. B24B 51/00; B24B 7/22; B24B 49/16

(52) U.S. Cl. CPC B24B 51/00; B24B 7/228; B24B 49/16

(57) ABSTRACT

An origin determination method includes the steps of adjusting a positional relation between a chuck table and a grinding unit by a moving mechanism such that lower ends of grinding stones and a holding surface are brought apart along a moving direction, moving the chuck table and the grinding unit relative to each other by the moving mechanism such that the lower ends of the grinding stones and the holding surface are brought closer to each other by a predetermined distance, and determining whether a measurement value of a load applied to the holding surface has reached a threshold. If the measurement value is determined to have reached the threshold, a positional relation between the chuck table and the grinding unit at that time is determined to be an origin of the moving mechanism. Otherwise, the step of moving and the step of determining are then performed again.

### BACKGROUND OF THE INVENTION

### Field of the Invention

The present invention relates to an origin determination method to be adopted for a grinding machine for grinding a plate-shaped workpiece, and a grinding machine.

### Description of the Related Art

To realize small and lightweight device chips, there are increasing occasions to thin a wafer, on a front surface side of which devices such as integrated circuits are disposed, by a method such as grinding. When a plate-shaped workpiece such as a wafer is ground, a grinding machine that includes a chuck table having a holding surface on which the workpiece is held and a grinding unit on which a grinding wheel having grinding stones is mounted is typically used.

With this grinding machine, the workpiece is first held on one surface thereof on the holding surface of the chuck table. With the grinding wheel and the chuck table each kept being rotated, the chuck table and the grinding unit are then moved relative to each other (are allowed to approach relative to each other) while liquid such as pure water is supplied, whereby the grinding stones are pressed from above against the other surface of the workpiece, and the workpiece is ground.

To grind a workpiece with high accuracy by use of a grinding machine such as that mentioned above, however, a need arises to accurately know a distance in a height direction between a holding surface of a chuck table and lower ends of grinding stones on a grinding wheel. Before grinding the workpiece, a positional relation between the chuck table and the grinding wheel when the holding surface and the lower ends of the grinding stones come into contact is therefore set as an origin, which serves as a reference, for the grinding machine (see, for example, Japanese Patent Laid-Open No. 2003-71712A).

### SUMMARY OF THE INVENTION

In the above-mentioned method, the contact between the holding surface and the lower ends of the grinding stones is detected based on a load applied to the chuck table. With this method, however, a predetermined time elapses from the detection of the contact between the holding surface and the lower ends of the grinding stones until a complete stop of the relative movement (approach) between the chuck table and the grinding wheel. There is accordingly a possibility that an excessively large load may be applied to the holding table and the grinding stones to cause damage to them.

The present invention therefore has as objects thereof the provision of an origin determination method, which can prevent damage to a chuck table and a grinding wheel, and a grinding machine, in which the origin determination method is adopted.

In accordance with a first aspect of the present invention, there is provided an origin determination method for use in determining an origin of a moving mechanism, where lower ends of grinding stones of a grinding wheel and a holding surface of a chuck table capable of holding a plate-shaped workpiece thereon come into contact with each other, in a grinding machine including the chuck table that has the holding surface, a grinding unit that has a spindle on which the grinding wheel with the grinding stones included thereon is mounted and grinds with the grinding wheel the workpiece held on the holding surface, the moving mechanism that has a motor and moves the chuck table and the grinding unit relative to each other in a moving direction intersecting the holding surface, and a load measurement unit that has a load sensor and measures a load applied to the holding surface. The origin determination method includes an adjustment step of adjusting a positional relation between the chuck table and the grinding unit by the moving mechanism such that the lower ends of the grinding stones and the holding surface are brought into a state in which the lower ends of the grinding stones and the holding surface are apart from each other along the moving direction, a moving step of, after the adjustment step, moving the chuck table and the grinding unit relative to each other by the moving mechanism such that the lower ends of the grinding stones and the holding surface are brought closer to each other by a predetermined distance smaller than a distance along the moving direction between the lower ends of the grinding stones and the holding surface as realized in the adjustment step, and a contact determination step of, after the moving step, measuring with the load sensor a load applied to the holding surface, and determining whether an acquired measurement value of the load has reached a threshold corresponding to a measurement value of a load when the lower ends of the grinding stones and the holding surface have come into contact with each other. If the measurement value acquired by the load sensor is determined to have reached the threshold in the contact determination step, a positional relation between the chuck table and the grinding unit at that time is determined to be the origin of the moving mechanism. If the measurement value acquired by the load sensor is determined not to have reached the threshold in the contact determination step, the moving step and the contact determination step are then performed again.

In accordance with a second aspect of the present invention, there is provided a grinding machine including a chuck table that has a holding surface capable of holding a plate-shaped workpiece thereon, a grinding unit that has a spindle on which a grinding wheel with grinding stones included thereon is mounted and grinds with the grinding wheel the workpiece held on the chuck table, a moving mechanism that has a motor, and moves the chuck table and the grinding unit relative to each other in a moving direction intersecting the holding surface, a load measurement unit that has a load sensor, and measures a load applied to the holding surface, and a controller that has a processing device and a storage device, and can control the moving mechanism and the load measurement unit according to a program stored in the storage device. The controller is configured to perform, according to the program, a procedure of adjusting a positional relation between the chuck table and the grinding unit by the moving mechanism such that lower ends of the grinding stones and the holding surface are brought into a state in which the lower ends of the grinding stones and the holding surface are apart from each other along the moving direction, a procedure of, after the procedure of adjusting the positional relation, moving the chuck table and the grinding unit relative to each other by the moving mechanism such that the lower ends of the grinding stones and the holding surface are brought closer to each other by a predetermined distance smaller than a distance along the moving direction between the lower ends of the grinding stones and the holding surface as realized in the procedure of adjusting, and a procedure of, after the procedure of moving the chuck table and the grinding unit relative to each other, measuring with the load sensor a load applied to the holding surface, and determining whether an acquired measurement value of the load has reached a threshold corresponding to a measurement value of a load when the lower ends of the grinding stones and the holding surface have come into contact with each other. If the measurement value acquired by the load sensor is determined to have reached the threshold in the procedure of determining whether the threshold has been reached, the positional relation between the chuck table and the grinding unit at that time is set to be an origin of the moving mechanism. If the measurement value acquired by the load sensor is determined not to have reached the threshold in the procedure of determining whether the threshold has been reached, the procedure of moving the chuck table and the grinding unit relative to each other and the procedure of determining whether the threshold has been reached are then performed again.

Preferably, the predetermined distance may be 1/7,000 or greater and 1/133 or smaller of the distance along the moving direction between the lower ends of the grinding stones and the holding surface. Also preferably, the predetermined distance may be 1 μm or greater and 15 μm or smaller.

With the origin determination method according to the first aspect and the grinding machine according to the second aspect of the present invention, after the chuck table and the grinding unit have been moved relative to each other such that the lower ends of the grinding stones and the holding surface are brought closer to each other by the predetermined distance, a load applied to the holding surface is measured by the load sensor, followed by determining whether the measurement value of the load has reached a threshold corresponding to the measurement value of a load when the lower ends of the grinding stones and the holding surface have come into contact with each other.

Therefore, the relative movement (approach) of the lower ends of the grinding stones and the holding surface has certainly come to a complete stop at the timing of determining whether the measurement value of the load has reached the threshold, so that, after the contact between the lower ends of the grinding stones and the holding surface, the load to be applied to the holding surface and the grinding stones will not extremely increase due to any relative movement (approach) between the chuck table and the grinding wheel.

According to the origin determination method of the first aspect and the grinding machine of the second aspect of the present invention, damage to the chuck table and grinding wheel is prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting a grinding machine according to an embodiment of the present invention;

FIG. 2 is a side view schematically depicting structures of a holding unit and a grinding unit in the grinding machine of FIG. 1;

FIG. 3 is a function block diagram schematically illustrating a functional structure of a controller in the grinding machine of FIG. 1;

FIG. 4 is a flow chart illustrating a series of procedures in an origin determination method according to the embodiment of the present invention;

FIG. 5 is a side view schematically depicting the holding unit and grinding unit, in which lower ends of grinding stones on a grinding wheel and an upper surface of a chuck table are still apart from each other after an operation to bring the chuck table and the grinding unit closer to each other has been repeated; and

FIG. 6 is a side view schematically depicting the holding unit and the grinding unit, in which the lower ends of the grinding stones on the grinding wheel and the upper surface of the chuck table are in contact with each other.

### DETAILED DESCRIPTION OF THE PREFERRED EMBODIMENT

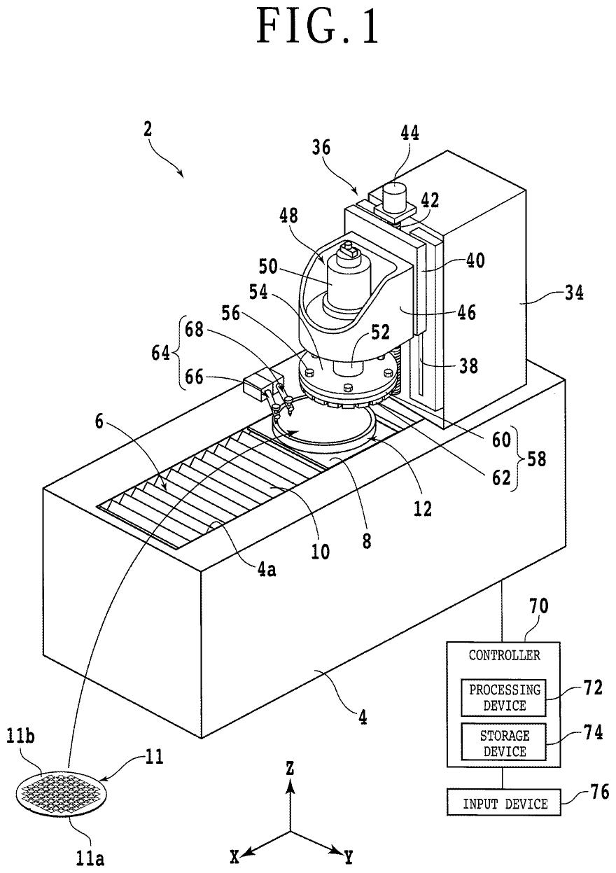

With reference to the attached drawings, a description will hereinafter be made in detail regarding an embodiment of the present invention. FIG. 1 is a perspective view schematically depicting a grinding machine 2 according to the embodiment of the present invention. In FIG. 1, some of various elements that constitute the grinding machine 2 are depicted in function blocks. An X-axis (first axis), a Y-axis (second axis), and a Z-axis (third axis) to be used in the following description are perpendicular to one another.

As depicted in FIG. 1, the grinding machine 2 includes a base 4, on which the various elements that constitute the grinding machine 2 are supported. Formed in an upper surface side of the base 4 is a cavity 4a that has an opening and is long in a direction (front-rear direction) substantially parallel to the X-axis. In the cavity 4a, an X-axis moving mechanism 6 of the ball screw type is arranged. The X-axis moving mechanism 6 includes a motor or the like (not depicted) connected to a ball screw, and a moving table (not depicted), and moves this moving table back and forth along the X-axis.

A table cover 8 covers the moving table from an upper side. To a front and rear of the table cover 8, corrugated, dust- and splash-proof covers 10 are attached. The corrugated, dust- and splash-proof covers 10 are expandable and contractible according to movement of the moving table (table cover 8). On an upper portion of the moving table, a holding unit 12 that is configured to allow holding of a plate-shaped workpiece 11 is arranged in such a fashion that the holding unit 12 is partly exposed from the table cover 8.

The workpiece 11 is, for example, a disk-shaped wafer made from a semiconductor material such as silicon. This workpiece 11 therefore has a circular front surface 11a, and a circular back surface 11b on a side opposite to the front surface 11a. The workpiece 11 is defined on the front surface 11a side into a plurality of small regions by a plurality of intersecting streets (scribe lines), and devices such as integrated circuits (ICs) are formed in the individual small regions.

The grinding machine 2 of this embodiment is used, for example, when grinding the workpiece 11 on the back surface 11b side. When grinding the workpiece 11 on the back surface 11b side, a protective member, typified by a protective tape made from a material such as a resin, can be bonded to the front surface 11a side of the workpiece 11. Owing to the bonding of the protective member to the front surface 11a side of the workpiece 11, impacts which are to be applied to the front surface 11a side during the grinding the back surface 11b side are moderated, so that the devices or the like on the workpiece 11 are protected.

In this embodiment, the disk-shaped wafer made from the semiconductor material such as silicon is used as the workpiece 11, but the material, a shape, a structure, a size, and the like of the workpiece 11 are not limited to those in this embodiment. For example, a substrate or the like made from a material such as, for example, another semiconductor, ceramics, resin, or metal can also be used as the workpiece 11. Similarly, the kind, number, shape, structure, size, arrangement, and the like of the devices are not limited to those mentioned above. No devices may be formed in the workpiece 11.

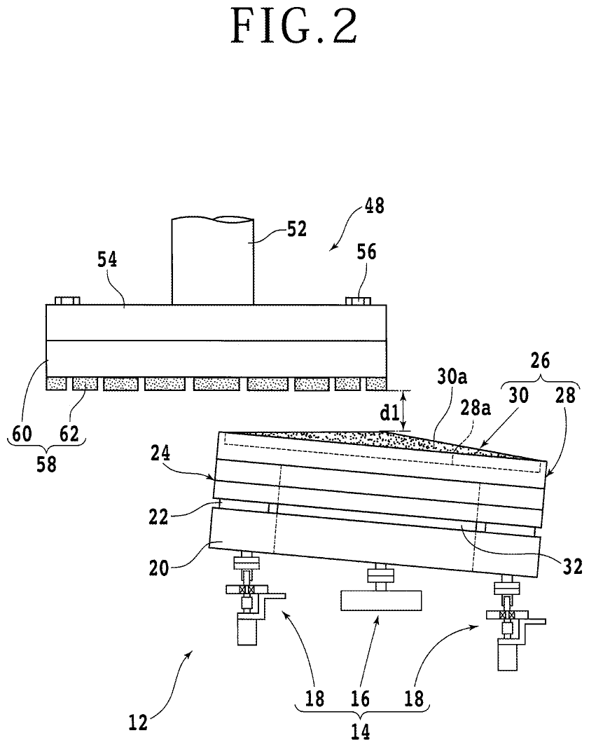

FIG. 2 is a side view schematically depicting structures of the holding unit 12 and the like. As depicted in FIG. 2, the holding unit 12 includes a tilt adjustment mechanism 14 arranged, for example, on the moving table of the X-axis moving mechanism 6. This tilt adjustment mechanism 14 includes one fixed support leg 16 and two adjustable support legs 18, and supports a disk-shaped table base 20 from below. Described specifically, to a lower surface of the table base 20, the fixed support leg 16 and the adjustable support legs 18 are connected at upper end portions thereof, respectively.

The height of an upper end of the fixed support leg 16 remains unchanged. On the other hand, the adjustable support legs 18 have actuators including motors, and are configured to be allowed to change the heights of their own upper ends. By changing the heights of the upper ends of the adjustable support legs 18, the tilt of the table base 20 is adjusted in a predetermined angle range.

On an upper surface of the table base 20, a chuck table 26 is arranged via a plurality of load sensors 22 and a bearing 24. The plurality of load sensors 22 are arranged, for example, at substantially equal angular intervals along a peripheral direction of the table base 20, and can measure a load applied to the chuck table 26. The load sensors 22 used in this embodiment are of the piezoelectric type, that is, are piezoelectric elements. The bearing 24 is, for example, a thrust bearing. However, load sensors 22 and a bearing 24 of other types may also be used.

The chuck table 26 includes a disk-shaped frame body 28 made from a material such as ceramics. This frame body 28 is supported at a lower surface thereof by the bearing 24. In an upper part of the frame body 28, a recess 28a is formed with an upper end thereof opened in a circular shape in an upper surface of the frame body 28. In the recess 28a, a holding plate 30 formed in a disk shape from a porous material such as porous ceramics is fixed.

An upper surface (holding surface) 30a of the holding plate 30 is formed, for example, in a shape corresponding to a side surface of a cone, and functions as a holding surface for holding the workpiece 11 or the like. The difference in height (height difference) between a center of the upper surface 30a of the holding plate 30, the center corresponding to an apex of the cone, and an outer peripheral edge of the upper surface 30a of the holding plate 30 is approximately 10 μm to 30 μm.

The holding plate 30 is connected on a lower surface side thereof to a suction source (not depicted) such as an ejector via a flow channel (not depicted) disposed inside the frame body 28, a valve (not depicted) arranged outside the frame body 28, and the like. If the valve is opened with the workpiece 11 (the protective member if it is bonded) or the like kept in contact with the upper surface 30a of the holding plate 30 and a negative pressure of the suction source acts on the holding surface 30a of the holding plate 30, the workpiece 11 or the like is drawn by the chuck table 26. The workpiece 11 or the like is therefore held by suction on the upper surface 30a of the chuck table 26.

The frame body 28 is connected to a motor (not depicted) via a spindle 32 arranged below the frame body 28, so that the chuck table 26 rotates about an axis of rotation of the spindle 32 by power of the motor or the like. In other words, the chuck table 26 is configured to be rotatable about an axis of rotation that intersects the upper surface 30a. If the tilt of the table base 20 is changed by the tilt adjustment mechanism 14, the tilt of the axis of rotation of the chuck table 26 is also changed.

If the moving table is moved back and forth along the X-axis by the X-axis moving mechanism 6, this chuck table 26 is also moved back and forth along the X-axis. Described more specifically, the X-axis moving mechanism 6 moves the chuck table 26, for example, between a front loading/unloading region where the workpiece 11 is loaded onto or unloaded from the chuck table 26 and a grinding region rear of the loading/unloading region.

As depicted in FIG. 1, a columnar support structure 34 is disposed rearward of the grinding region (rearward of the X-axis moving mechanism 6). On a front surface side of the support structure 34, a Z-axis moving mechanism 36 is arranged. The Z-axis moving mechanism 36 includes a pair of guide rails 38 that are substantially parallel to the Z-axis and are long in an up-down direction, and to these paired guide rails 38, a moving plate 40 is attached in such a fashion that it is slidable.

On a rear surface side of the moving plate 40, a nut portion (not depicted) that constitutes a ball screw is disposed, and to this nut portion, a threaded shaft 42 that is substantially parallel to the Z-axis is coupled in a rotatable fashion. On an end portion of the threaded shaft 42, a motor 44 or the like is connected. By rotating the threaded shaft 42 with the motor 44 or the like, the moving plate 40 is moved up and down along the guide rails 38.

On a front surface of the moving plate 40, a support bracket 46 is disposed. Supported on the support bracket 46 is a grinding unit 48 that can grind the workpiece 11 held on the chuck table 26 in the grinding region. The grinding unit 48 includes a spindle housing 50 fixed on the support bracket 46. In the spindle housing 50, a spindle 52 that serves as a rotary shaft parallel to the Z-axis or as a rotary shaft slightly inclined with respect to the Z-axis is accommodated in such a fashion that the spindle 52 can rotate about its axis center.

The spindle 52 is exposed at a lower end portion thereof from a lower end surface of the spindle housing 50, and on the lower end portion of the spindle 52, a disk-shaped mount 54 is fixed. In an outer edge portion of the mount 54, for example, a plurality of holes (not depicted) are formed extending through the mount 54 in a direction of its thickness. Fixing members 56 such as bolts are inserted in the respective holes.

On a lower surface of the mount 54, a grinding wheel 58 is secured by the above-mentioned fixing members 56. Therefore, the grinding wheel 58 is mounted on the spindle 52. In the spindle housing 50, a motor (not depicted) or the like connected to an upper end side of the spindle 52 is accommodated. By power of this motor or the like, the grinding wheel 58 is rotated along with the spindle 52.

The grinding wheel 58 includes an annular wheel base 60 formed with use of metal such as stainless steel or aluminum. On a lower surface of the wheel base 60, a plurality of grinding stones 62, in which abrasive grits such as diamond are dispersed in a binder such as a vitrified bond or a resinoid bond, are fixed along a peripheral direction of the wheel base 60. The size of the abrasive grits, the kind of the binder, and the like are appropriately set according to the quality and the like required for the ground workpiece 11.

Arranged below the grinding unit 48 is a nozzle (not depicted) that can supply a liquid (grinding fluid) such as pure water to contacting portions of the workpiece 11 and the grinding stones 62. Instead of this nozzle, or in addition to the nozzle, a liquid supply port that is used to supply the liquid may be disposed in the grinding wheel 58 or the like.

Disposed beside the grinding region is a thickness gauge 64 that is used when measuring the thickness or the like of the workpiece 11 under grinding. The thickness gauge 64 includes a first height gauge 66 arranged above the frame body 28 of the chuck table 26, and a second height gauge 68 arranged above the holding plate 30. For example, the height of the upper surface of the frame body 28 is measured by the first height gauge 66, and the height of the upper surface of the workpiece 11 held on the chuck table 26 is measured by the second height gauge 68. The difference between these measurement values is the thickness of the workpiece 11.

To the individual elements of the grinding machine 2, a controller (control unit) 70 is connected. This controller 70 is configured of a computer that includes, for example, a processing device 72 and a storage device 74, and controls operation and the like of the above-mentioned individual elements of the grinding machine 2 such that the workpiece 11 is appropriately ground.

The processing device 72 is typically a central processing unit (CPU), and performs various kinds of processing required to control the above-mentioned elements. The storage device 74 includes, for example, a main storage device such as a dynamic random access memory (DRAM), and an auxiliary storage device such as a hard disk drive or a flash memory. Functions of the controller 70 are realized, for example, by operation of the processing device 72 according to a program stored in the storage device 74.

To the controller 70, an input device 76 is connected. The input device 76 is, for example, a touch screen, and inputs operator's instructions into the controller 70. This touch screen also serves as a display device that displays information outputted from the controller 70. A keyboard, a mouse, or the like may also be adopted as the input device 76.

Stored in a part of the storage device 74, the part being a non-transitory recording medium readable by the computer or the like, is a program that allows the processing device 72 to perform a series of procedures needed for the grinding of the workpiece 11. The processing device 72 therefore performs the series of procedures, which are needed for the grinding of the workpiece 11, according to this program.

When grinding the workpiece 11, the controller 70, for example, holds the workpiece 11 on the upper surface 30a of the chuck table 26, and moves this chuck table 26 from the loading/unloading region to the grinding region. Then, the controller 70 rotates the chuck table 26 and the grinding wheel 58 relative to each other, and while supplying the liquid from the nozzle, lowers the grinding unit 48.

In other words, the controller 70 moves the chuck table 26 and the grinding unit 48 relative to each other by the Z-axis moving mechanism 36 in the moving direction, which intersects the upper surface 30a of the holding plate 30, so that the upper surface 30a of the holding plate 30 and the lower ends of the grinding stones 62 are brought closer to each other. As a consequence, the grinding stones 62 come into contact with the upper surface of the workpiece 11 held on the chuck table 26, whereby the workpiece 11 is ground.

Further, in the grinding machine 2 of this embodiment, the origin of the Z-axis moving mechanism 36, which is used as a reference for the positional relation between the chuck table 26 and the grinding unit 48, is determined in a predetermined fashion specified by the program. The program for allowing the processing device 72 to perform a series of procedures needed for the determination of the origin of the Z-axis moving mechanism 36 is hence stored in a predetermined part of the storage device 74. The processing device 72 therefore performs the series of procedures, which are needed for the determination of the origin, according to this program.

The origin of the Z-axis moving mechanism 36 is determined so as to realize a state in which the upper surface 30a of the holding plate 30 and the lower ends of the grinding stones 62 come into contact with each other. At the origin of the Z-axis moving mechanism 36, the distance between the upper surface 30a of the holding plate 30 and the lower ends of the grinding stones 62 is zero accordingly. Using information on this origin, the controller 70 realizes high-accuracy grinding of the workpiece 11. The controller 70 is not absolutely required to hold information on the origin itself if it can hold information needed to ascertain the origin.

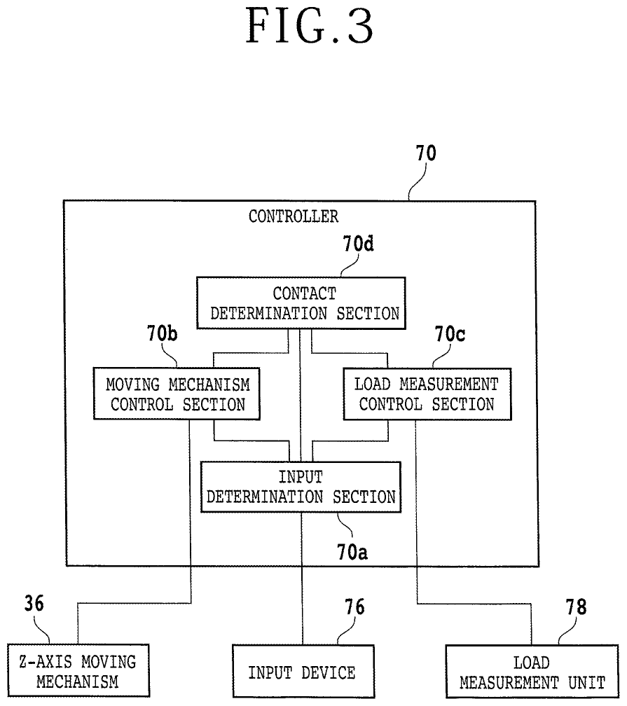

FIG. 3 is a function block diagram schematically illustrating a functional structure of the controller 70 to be realized by the program in this embodiment. In FIG. 3, the Z-axis moving mechanism 36, the input device 76, the load measurement unit 78, and the like, all of which are connected to the controller 70, are depicted along with the controller 70 for the sake of convenience of description.

As depicted in FIG. 3, the controller 70 includes an input determination section 70a that determines an input from the input device 76. When a command is inputted from the input device 76, for example, to the effect that an origin determination mode, in which the series of procedures for the determination of the origin (specifically, an origin determination method according to the embodiment) are to be performed, is to be started, the input determination section 70a notifies a moving mechanism control section 70b, a load measurement control section 70c, and a contact determination section 70d of that effect.

When the notification is received from the input determination section 70a, the moving mechanism control section 70b and the load measurement control section 70c perform procedures which are needed for the origin determination mode according to the notifications, using the Z-axis moving mechanism 36 and the load measurement unit 78, respectively. The load measurement unit 78 includes, for example, the above-mentioned load sensors 22, an information processing section (not depicted) that processes information outputted from the load sensors 22, and the like, and is configured to allow measurement of a load applied to the upper surface 30a of the holding plate 30.

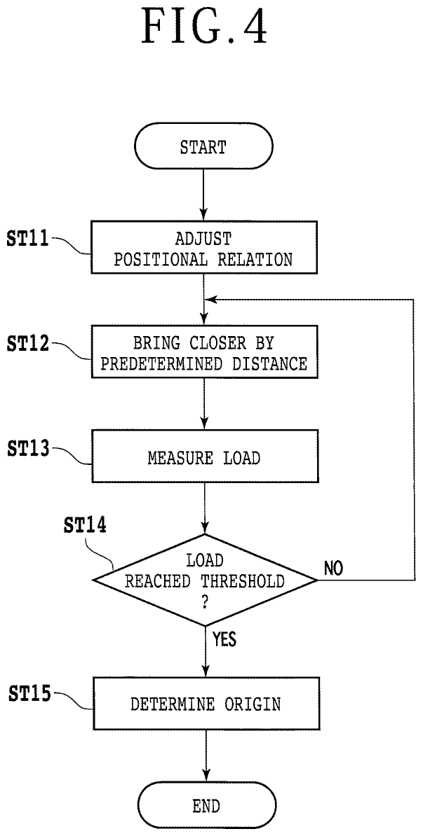

FIG. 4 is a flow chart illustrating the series of procedures for the determination of the origin, that is, the origin determination method according to this embodiment. When the notification is received from the input determination section 70a to the effect that the origin determination mode is to be started, the moving mechanism control section 70b first performs a procedure to adjust by the Z-axis moving mechanism 36 the positional relation between the chuck table 26 and the grinding unit 48 such that the upper surface 30a of the holding plate 30 and the lower ends of the grinding stones 62 are kept apart from each other along the moving direction (adjustment step ST11).

Described specifically, the moving mechanism control section 70b operates the Z-axis moving mechanism 36 to move the chuck table 26 and the grinding unit 48 relative to each other along the moving direction such that the upper surface 30a of the holding plate 30 and the lower ends of the grinding stones 62 are sufficiently separated from each other along the moving direction. This procedure is performed using, for example, only information inherent to the Z-axis moving mechanism 36 as determined at a design stage, without using information on the origin of the Z-axis moving mechanism 36.

As a result, as depicted in FIG. 2, a clearance is formed between the upper surface 30a of the holding plate 30 and the lower ends of the grinding stones 62 irrespective of the kinds, conditions, and the like of the chuck table 26 and the grinding wheel 58. A distance d1 between the upper surface 30a of the holding plate 30 and the lower ends of the grinding stones 62 is 2 mm or greater and 7 mm or smaller in this embodiment. However, another distance d1 outside this range may also be realized.

After the positional relation between the chuck table 26 and the grinding unit 48 has been adjusted, the moving mechanism control section 70b performs a procedure to move the chuck table 25 and the grinding unit 48 relative to each other by the Z-axis moving mechanism 36 such that the upper surface 30a of the holding plate 30 and the lower ends of the grinding stones 62 are brought closer to each other by a predetermined distance smaller than the distance d1 at the time of the completion of the procedure to adjust the positional relation (moving step ST12).

If, with the upper surface 30a of the holding plate 30 and the lower ends of the grinding stones 62 kept in contact with each other, for example, the Z-axis moving mechanism 36 is operated to bring the chuck table 26 and the grinding unit 48 still closer to each other, the load applied to the holding plate 30 and the grinding stones 62 becomes greater as the distance of this approach (the operating amount by the Z-axis moving mechanism 36) increases. If the distance of approach exceeds 15 μm, the load applied to the holding plate 30 and the grinding stones 62 becomes greater than 500 N, so that the holding plate 30 and the grinding stones 62 are likely to be damaged.

The predetermined distance by which the upper surface 30a of the holding plate 30 and the lower ends of the grinding stones 62 are brought closer to each other is therefore set at 15 μm or smaller. This significantly suppresses the possibility of damage to the holding plate 30 and the grinding stones 62. If the distance by which the upper surface 30a of the holding plate 30 and the lower ends of the grinding stones 62 are brought further closer to each other from the state in which they are in contact with each other (the operating amount by the Z-axis moving mechanism 36) is 10 μm or smaller, the load applied to the holding plate 30 and the grinding stones 62 is also kept at 200 N or less, so that the holding plate 30 and the grinding stones 62 are not damaged substantially. It is therefore desired to set the predetermined distance at 10 μm or smaller.

If the predetermine distance by which the upper surface 30a of the holding plate 30 and the lower ends of the grinding stones 62 are brought closer to each other is extremely small, on the other hand, a substantial time is needed for the determination of the origin. In this embodiment, the predetermined distance is hence set at 1 μm or greater. This enables the origin to be determined in a short period of time, posing no problem for practical use. From a viewpoint of reducing the time required for the determination of the origin, the predetermined distance may desirably be set at 2 μm or greater.

Taking into consideration that the distance d1 between the upper surface 30a of the holding plate 30 and the lower ends of the grinding stones 62 at the time of initiation of the adjustment step ST11 is 2 mm or greater and 7 mm or smaller in this embodiment, the predetermined distance is 1/7,000 ( 1/7,000 μm) or greater and 1/133 ( 15/2,000 μm) or smaller of the distance d1. However, another predetermined distance outside this range may be adopted if the possibility of damage to the holding plate 30 and the grinding stones 62 can be suppressed low.

When the upper surface 30a of the holding plate 30 and the lower ends of the grinding stones 62 are brought closer to each other, the speed of their relative movement can be appropriately set, for example, in a range of 1 mm/s and higher and 20 mm/s or lower. In this embodiment, the speed of this relative movement is set at 5 mm/s. However, another relative movement speed outside the above-mentioned range may be adopted.

After the procedure of bringing the chuck table 26 and the grinding unit 48 closer to each other by the predetermined distance by moving them relative to each other, the load measurement control section 70c performs a procedure to measure, with the load measurement unit 78 including the load sensors 22, a load applied to the upper surface 30a of the holding plate 30 (measurement step ST13). The waiting time until the measurement of the load by the load sensors 22 is 10 ms or longer and 100 ms or shorter, typically, substantially 20 ms.

After the load applied to the upper surface 30a of the holding plate 30 has been measured, the contact determination section 70d performs a procedure to compare the measurement value of the load with a predetermined threshold (contact determination step ST14). The threshold is a value corresponding to the measurement value of the load when the upper surface 30a of the holding plate 30 and the lower ends of the grinding stones 62 have come into contact with each other and is stored in the storage device 74 in advance.

Described specifically, upon contact between the upper surface 30a of the holding plate 30 and the lower ends of the grinding stones 62, the measurement value of the load reaches the threshold (the measurement value of the load>the threshold, or the measurement value of the load≥the threshold). If the upper surface 30a of the holding plate 30 and the lower ends of the grinding stones 62 are out of contact, on the other hand, the measurement value of the load has not reached the threshold (the measurement value of the load≤the threshold, or the measurement value of the load<the threshold).

If the measurement value of the load has not reached the threshold (“NO” in the contact determination step ST14), the contact determination section 70d notifies the moving mechanism control section 70b and the load measurement control section 70c to perform the predetermined procedures again. Upon reception of this notification, the moving mechanism control section 70b again performs the procedure to move the chuck table 26 and the grinding unit 48 relative to each other by the Z-axis moving mechanism 36 such that the upper surface 30a of the holding plate 30 and the lower ends of the grinding stones 62 are brought further closer to each other by the predetermined distance (the movement step ST12).

Further, the load measurement control section 70c again performs the procedure to measure, with the load measurement unit 78 including the load sensors 22, a load applied to the upper surface 30a of the holding plate 30 (the measurement step ST13). Then, the contact determination section 70d again performs the procedure to compare the measurement value of a load with the predetermined threshold (the contact determination step ST14).

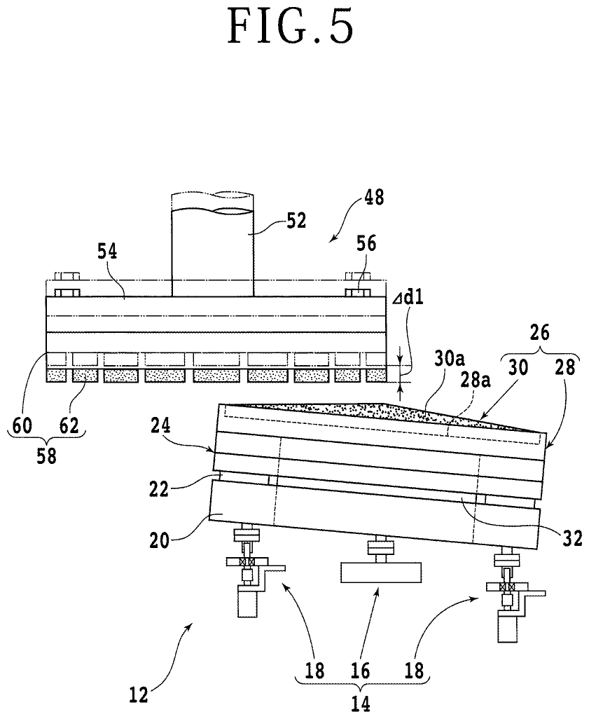

FIG. 5 is a side view schematically depicting the holding unit 12 and the grinding unit 48, in which the lower ends of the grinding stones 62 on the grinding wheel 58 and the upper surface 30a of the holding plate 30 are still apart from each other after the operation to bring the chuck table 26 and the grinding unit 48 closer to each other in the movement step ST12 has been repeated. If the operation to bring the chuck table 26 and the grinding unit 48 closer to each other is repeated n times, for example, the upper surface 30a of the holding plate 30 and the lower ends of the grinding stones 62 are brought closer to each other by Δd1 (=n×the predetermined distance) compared with the distance d1 at the time of the completion of the procedure to adjust the positional relation.

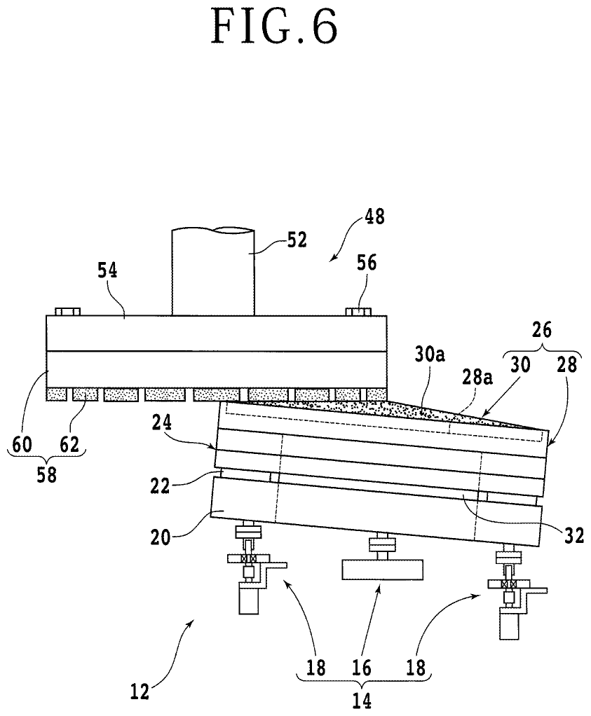

If the measurement value of the load has reached the threshold (“YES” in the contact determination step ST14), the contact determination section 70d determines the positional relation between the chuck table 26 and the grinding unit 48 at that time to be the origin of the Z-axis moving mechanism 36 (origin determination step ST15). FIG. 6 is a side view schematically depicting the holding unit 12 and the grinding unit 48, in which the lower ends of the grinding stones 62 on the grinding wheel 58 and the upper surface 30a of the chuck table 26 are in contact with each other.

Information on the origin so determined is stored in the storage device 74. In the grinding machine 2, the new origin of the Z-axis moving mechanism 36 is set. This origin is used in the procedures to grind the next workpiece 11. This realizes high-accuracy grinding of the workpiece 11.

In the origin determination method and the grinding machine 2 according to the above-described embodiment, after moving the chuck table 26 and the grinding unit 48 relative to each other such that the lower ends of the grinding stones 62 and the upper surface (holding surface) 30a of the holding plate 30 are brought closer to each other by the predetermined distance, the load applied to the upper surface 30a of the holding plate 30 is measured by the load sensors 22, followed by determining whether the measurement value of the load has reached the threshold corresponding to the measurement value of the load when the lower ends of the grinding stones 62 and the upper surface 30a of the holding plate 30 have come into contact with each other.

The relative movement (approach) of the lower ends of the grinding stones 62 and the upper surface 30a of the holding plate 30 has certainly come to a complete stop at the timing of determining whether the measurement value of the load has reached the threshold, so that, after the contact between the lower ends of the grinding stones 62 and the upper surface 30a of the holding plate 30, the load to be applied to the upper surface 30a of the holding plate 30 and the grinding stones 62 will not extremely increase, although such an extreme increase of the load is prone to occur if relative movement (approach) would otherwise take place between the chuck table 26 and the grinding wheel 62. Damage to the chuck table 26 and the grinding wheel 58 is prevented accordingly.

The present invention can be practiced with various modifications without limitations by the foregoing description of the embodiment. Upon determination of the origin, for example, the chuck table 27 and the grinding wheel 58 are not rotated in the above-mentioned embodiment. The origin may however be determined while they are rotated, if a load associated with such rotation poses no problem.

In the above-mentioned embodiment, the program that realizes the procedures for the determination of the origin is stored in the storage device 74 of the controller 70. This program may however be recorded, for example, in a desired non-transitory recording medium readable by the computer or the like. For example, this program may be recorded in an optical disc that can be distributed at low cost, such as a compact disc (CD).

Moreover, Other structures, methods, and the like according to the abovementioned embodiment and modifications can be implemented by appropriately being modified within a scope not departing from the object of the present invention.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. An origin determination method for use in determining an origin of a moving mechanism, where lower ends of grinding stones of a grinding wheel and a holding surface of a chuck table capable of holding a plate-shaped workpiece thereon come into contact with each other, in a grinding machine including
the chuck table that has the holding surface,
a grinding unit that has a spindle on which the grinding wheel with the grinding stones included thereon is mounted and grinds with the grinding wheel the workpiece held on the holding surface,
the moving mechanism that has a motor and moves the chuck table and the grinding unit relative to each other in a moving direction intersecting the holding surface, and
a load measurement unit that has a load sensor and measures a load applied to the holding surface,
the origin determination method comprising:
an adjustment step of adjusting a positional relation between the chuck table and the grinding unit by the moving mechanism such that the lower ends of the grinding stones and the holding surface are brought into a state in which the lower ends of the grinding stones and the holding surface are apart from each other along the moving direction,
a moving step of, after the adjustment step, moving the chuck table and the grinding unit relative to each other by the moving mechanism such that the lower ends of the grinding stones and the holding surface are brought closer to each other by a predetermined distance smaller than a distance along the moving direction between the lower ends of the grinding stones and the holding surface as realized in the adjustment step, and
a contact determination step of, after the moving step, measuring with the load sensor a load applied to the holding surface, and determining whether an acquired measurement value of the load has reached a threshold corresponding to a measurement value of a load when the lower ends of the grinding stones and the holding surface have come into contact with each other,
wherein, if the measurement value acquired by the load sensor is determined to have reached the threshold in the contact determination step, a positional relation between the chuck table and the grinding unit at that time is determined to be the origin of the moving mechanism, and,
if the measurement value acquired by the load sensor is determined not to have reached the threshold in the contact determination step, the moving step and the contact determination step are then performed again.

2. The origin determination method according to claim 1,
wherein the predetermined distance is 1/7,000 or greater and 1/133 or smaller of the distance along the moving direction between the lower ends of the grinding stones and the holding surface.

3. The origin determination method according to claim 1,
wherein the predetermined distance is 1 μm or greater and 15 μm or smaller.

4. A grinding machine comprising:
a chuck table that has a holding surface capable of holding a plate-shaped workpiece thereon;
a grinding unit that has a spindle on which a grinding wheel with grinding stones included thereon is mounted and grinds with the grinding wheel the workpiece held on the chuck table;
a moving mechanism that has a motor, and moves the chuck table and the grinding unit relative to each other in a moving direction intersecting the holding surface;
a load measurement unit that has a load sensor, and measures a load applied to the holding surface; and
a controller that has a processing device and a storage device, and can control the moving mechanism and the load measurement unit according to a program stored in the storage device,
wherein the controller is configured to perform, according to the program,
a procedure of adjusting a positional relation between the chuck table and the grinding unit by the moving mechanism such that lower ends of the grinding stones and the holding surface are brought into a state in which the lower ends of the grinding stones and the holding surface are apart from each other along the moving direction,
a procedure of, after the procedure of adjusting the positional relation, moving the chuck table and the grinding unit relative to each other by the moving mechanism such that the lower ends of the grinding stones and the holding surface are brought closer to each other by a predetermined distance smaller than a distance along the moving direction between the lower ends of the grinding stones and the holding surface as realized in the procedure of adjusting, and
a procedure of, after the procedure of moving the chuck table and the grinding unit relative to each other, measuring with the load sensor a load applied to the holding surface, and determining whether an acquired measurement value of the load has reached a threshold corresponding to a measurement value of a load when the lower ends of the grinding stones and the holding surface have come into contact with each other,
if the measurement value acquired by the load sensor is determined to have reached the threshold in the procedure of determining whether the threshold has been reached, the positional relation between the chuck table and the grinding unit at that time is set to be an origin of the moving mechanism, and,
if the measurement value acquired by the load sensor is determined not to have reached the threshold in the procedure of determining whether the threshold has been reached, the procedure of moving the chuck table and the grinding unit relative to each other and the procedure of determining whether the threshold has been reached are then performed again.

5. The grinding machine according to claim 4,
wherein the predetermined distance is 1/7,000 or greater and 1/133 or smaller of the distance along the moving direction between the lower ends of the grinding stones and the holding surface.

6. The grinding machine according to claim 4,
wherein the predetermined distance is 1 μm or greater and 15 μm or smaller.
